(19) United States
(12) Patent Application Publication
(10) Pub. No.: US 2010/0059752 A1
(43) Pub. Date: Mar. 11, 2010

(54) DISPLAY SUBSTRATE, METHOD OF MANUFACTURING THE SAME

(76) Inventors: Jeong-Ho Lee, Seoul (KR); Jung-Suk Bang, Guri-si (KR)

Correspondence Address: Innovation Counsel LLP, 21771 Stevens Creek Blvd, Ste. 200A, Cupertino, CA, 95014, US

(21) Appl. No.: 12/209,073

(22) Filed: Sep. 11, 2008

(51) Int. Cl. H01L 29/04; H01L 21/84

(52) U.S. Cl. 257/59; 438/155; 257/E29.003; 257/E21.7

(57) ABSTRACT

A method of manufacturing a display substrate and a display substrate manufactured by the same that are capable of improving display quality are presented. The method includes forming a gate wiring, a data wiring, a thin film transistor connected to the gate wiring and the data wiring respectively, and a protective insulating layer covering the gate wiring, the data wiring and the thin film transistor; forming a first black matrix pattern on the protective insulating layer; forming a protective insulating layer pattern by etching a part of the protective insulating layer by using the first black matrix pattern as an etching mask; forming a second black matrix pattern exposing at least one pixel region by removing a part of the first black matrix pattern; forming a color filter on the pixel region; and forming a pixel electrode electrically connected to the thin film transistor on at least a part of the color filter.

### BACKGROUND OF THE INVENTION

1. Technical Field

The present invention relates to a display substrate and a method of manufacturing the same, and more particularly, a display substrate for displaying an image and a method of manufacturing the same.

2. Discussion of the Related Art

A liquid crystal display device which is a display device for displaying images includes a display substrate, a counter substrate disposed opposite the display substrate, and a liquid crystal layer disposed between the two substrates.

Generally, a display substrate includes gate wirings, data wirings, thin film transistors and pixel electrodes that are formed on the transparent substrate to drive a plurality of pixels independently. The counter substrate includes red, green and blue color filters, a black matrix and a common electrode opposite the pixel electrode.

Recently, for simplifying a process for making the counter substrate, a process forming the color filter and the black matrix on the display substrate has been developed. By introducing such a process, the alignment margin between the display substrate and the counter substrate has increased and the aperture ratio has increased, but the manufacturing cost has decreased due to the simplification of the process for making the counter substrate.

However, in a structure made by such a process, damage of a layer formed on a pixel region of the display substrate which was generated by remnants of the manufacturing process remained, and thus, stains was appeared when driving the display.

### SUMMARY OF THE INVENTION

Embodiments of the present invention provide a display substrate capable of preventing the stains from being generated when driving the display thereby improving display quality.

An embodiment of the present invention provides a method of manufacturing the display substrate.

The present invention discloses a display substrate having a gate signal line formed on a substrate, a data signal line being insulated from the gate signal line and crossing the gate signal line, a thin film transistor connected to the gate signal line and the data signal line, respectively, a black matrix formed on the thin film transistor and at least one of the gate signal line and data signal line, and including photosensitive material, a protective insulating layer formed between the thin film transistor and the black matrix, a pixel electrode electrically connected to the thin film transistor through a contact hole formed in the protective insulating layer, and a color filter formed between the protective insulating layer and the pixel electrode, and having an opening that exposes the contact hole.

The black matrix is formed by using a slit mask or a halftone mask.

An organic layer can further be formed between the pixel electrode and the black matrix, and between the pixel electrode and the color filter. By forming the organic layer, contamination of the liquid crystal layer caused by gas leaked from the color filter or other layers can be prevented.

Meanwhile, a storage line and a storage electrode, both of which are formed on a same layer as the gate signal line can further be formed. In such a case, it is preferable that the pixel electrode is electrically connected to a drain electrode of the thin film transistor through the opening and the contact hole, and at least a part of the storage electrode overlaps the drain electrode. The storage electrode and the drain electrode overlaps the storage electrode from the storage capacitor with a gate insulating layer being therebetween.

The present invention also discloses a method of manufacturing a display substrate including, forming a gate wiring, a data wiring, a thin film transistor connected to the gate wiring and the data wiring respectively, and a protective insulating layer covering the gate wiring, the data wiring and the thin film transistor; forming a first black matrix pattern on the protective insulating layer; forming a protective insulating layer pattern by etching a part of the protective insulating layer by using the first black matrix pattern as an etching mask; forming a second black matrix pattern exposing at least one pixel region by removing a part of the first black matrix pattern; forming a color filter on the pixel region; and forming a pixel electrode electrically connected to the thin film transistor on at least a part of the color filter.

Forming the first black matrix pattern includes, forming a first organic layer including a photosensitive material on the protective insulating layer, exposing the first organic layer by using a slit mask or a halftone mask, and forming a first portion having first thickness, a second portion having second thickness thinner than the first thickness, and a third portion exposing the protective insulating layer by developing the first organic layer.

Forming the protective insulating layer pattern includes forming a contact hole exposing the drain electrode of the thin film transistor by dry etching the protective insulating layer exposed by the third portion.

Forming the second black matrix pattern includes removing the second portion from the substrate.

### BRIEF DESCRIPTION OF THE DRAWINGS

The above and other features of the present disclosure will become more apparent by describing exemplary embodiments thereof with reference to the accompanying drawings, in which:

FIG. 1 is a plan view roughly showing a display substrate according to a first exemplary embodiment of the present invention,

FIG. 2 is a cross sectional view taken along line □-□′ of FIG. 1,

FIG. 3 is a cross sectional view taken along lines □-□′, □-□′ of FIG. 1,

FIG. 4 is an enlarged view roughly showing a part of a pixel region of a display substrate according to a second exemplary embodiment of the present invention,

FIG. 5 is a cross sectional view taken along line V-V′ of FIG. 4,

FIG. 6 to FIG. 14 are cross sectional views showing a method of manufacturing a display substrate shown in FIG. 1.

### DETAILED DESCRIPTION OF THE EXEMPLARY EMBODIMENTS

The invention is described more fully hereinafter with reference to the accompanying drawings, in which embodiments of the invention are shown. This invention may, however, be embodied in many different forms and should not be construed as limited to the embodiments set forth herein. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present.

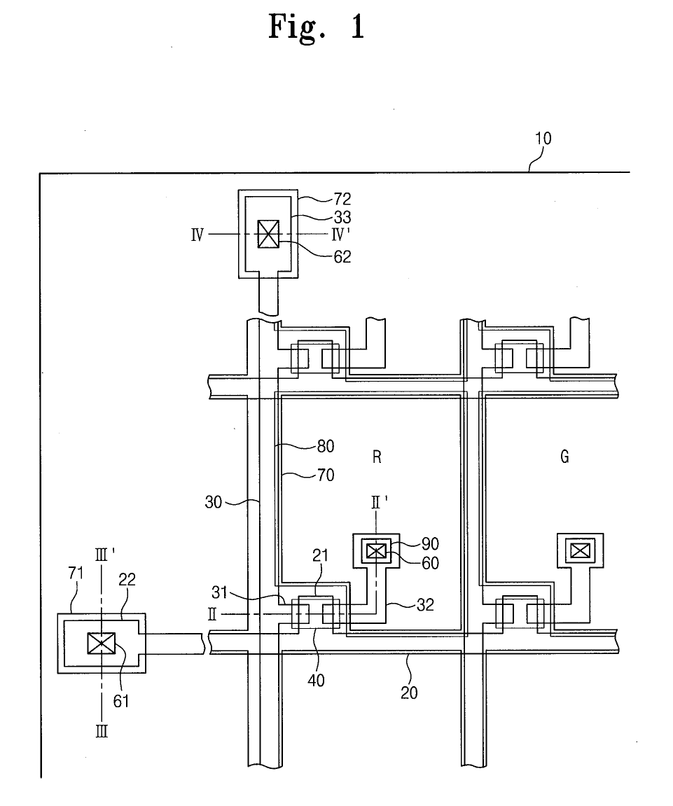

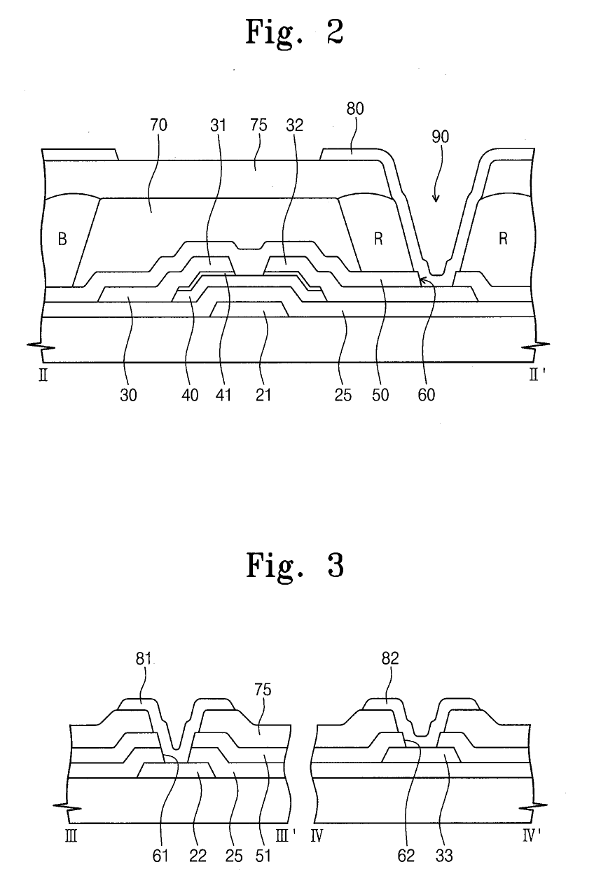

FIG. 1. is a plan view roughly showing a display substrate according to a first exemplary embodiment of the present invention, FIG. 2 is a cross sectional view taken along line □-□′ of FIG. 1, and FIG. 3 is a cross sectional view taken along lines □-□′, □-□′ of FIG. 1.

Referring to FIG. 1 to FIG. 3, a plurality of gate wirings are formed on a substrate 10 which is made of, for example, a transparent glass, quartz or plastic. The gate wiring includes a plurality of gate signal lines 20 extended in a first direction, gate electrodes 21 of a thin film transistors connected to the gate signal line 20 and gate pad electrodes 22 formed at an end portions of the gate signal lines 20. The gate wiring 20, 21, 22 may be formed as a single layer or multiple layer including metal or alloy of at least one of Aluminum Al, Copper Cu, Silver Ag, Molybdenum Mo, Chrome Cr, Tantalum Ta or Titanium Ti.

A gate insulating layer 25 is disposed on the gate wiring 20, 21, 22. The gate insulating layer may be formed as a single layer or multiple layer including Silicon oxide SiOx or Silicon nitride SiNx

A semiconductor layer 40 made from amorphous silicon, and an ohmic contact layer 41 made from amorphous silicon heavily doped with n+ dopant are disposed on the gate insulating layer 25.

A plurality of data wirings made from conductive material are disposed on the ohmic contact layer 41. The data wirings 30, 31, 32, 33 include data signal lines 30 extended in a second direction that is, for example, perpendicular to the first direction, source electrodes 31 connected to the data signal lines 30, drain electrodes 32 separated from the source electrodes 32, and data pad electrodes 33 formed at an end portion of the data signal lines 30.

The data wiring 30, 31, 32, 33 may be formed as a single layer or multiple layer including metal or alloy of at least one of Aluminum Al, Copper Cu, Silver Ag, Molybdenum Mo, Chrome Cr, Tantalum Ta or Titanium Ti.

A protective insulating layer 50 made from, for example, Silicon nitride SiNx is disposed on the data wirings 30, 31, 32, 33. In the protective insulating layer, a first contact hole 60 exposes a part of the drain electrode 32, a second contact hole 61 exposes the gate pad electrode 22, and a third contact hole 62 exposes the data pad electrode 33. A shown in FIG. 3, the second contact hole 62 is formed in the gate insulating later 25 as well as the protective insulating layer 50 to expose the gate pad electrode 22.

Color filters R, G, B are disposed on each pixel region formed near a crossing region of the gate signal line 20 and the data signal line 30 such that light is substantially transmitted therethrough. The color filters R, G, B may includes pigment or resin representing the colors red R, green G or blue B. It is preferable for the color filters R, G, B to have flat surface so that color purity can be controlled accurately. An opening 90 exposing the contact hole 60 of the protective insulating layer is formed in the color filter R, G, B

A black matrix covering the gate signal lines 20, the data signal lines 30 and the thin film transistors is disposed at each border of the red R, green G, and blue B color filters. The black matrix can be made from an organic composition including, for example, Carbon black. The organic composition may further include photosensitive material for the merit of omitting an etching process. However, the black matrix 70 is not limited to the above, and can be made from an opaque metal like Chrome Cr, or can be made as a double layer of opaque metal and organic material.

In the meantime, although the black matrix 70 is formed as a matrix type that extends in the first and second directions and covers both the gate signal line 20 and the data signal line 30 in the present embodiment, the figure of the black matrix is not limited to the above. Namely, the black matrix can be formed to have various figures according to the alignment of the color filters R, G, B such that the black matrix can be formed as a stripe type that extends in the first direction and covers the gate signal line 20, or extends in the second direction and covers the data signal line 30.

An organic layer may be further disposed on the color filter R, G, B and the black matrix 70, and due to such a structure, a contamination of the liquid crystal layer not shown caused by gas leaked from the color filter or other layers can be prevented.

A pixel electrode 80 electrically connected to the drain electrode 32 through the contact hole 60 and the opening 90 is disposed on the organic layer. The pixel electrode 80 can be made from a transparent conductive material like ITO or IZO. The pixel electrode can be made from conductive material that has high reflexibility like Aluminum Al, Copper Cu or Silver Ag, according to the mode adopted to the display substrate. Although this embodiment of the invention is described as having one pixel electrode disposed per pixel region, the pixel electrode can be separated by two or more portions in a pixel region. The pixel electrode can be formed to have various figures that have been already disclosed.

In the meantime, as shown in FIG. 3, a first auxiliary element 81 electrically connected to the gate pad electrode 22 through the second contact hole 61 is disposed on the gate pad electrode 22, and a second auxiliary element 82 electrically connected to the data pad electrode 33 through the third contact hole 62 is disposed on the data pad electrode 33. The first and second auxiliary elements 81, 82 are made from the same material as the pixel electrode 80.

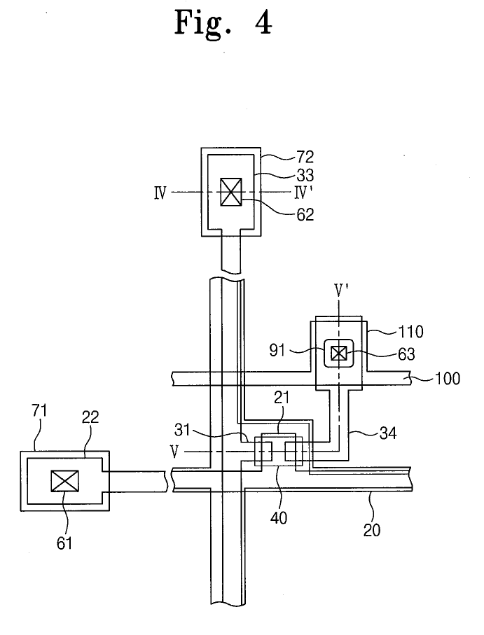

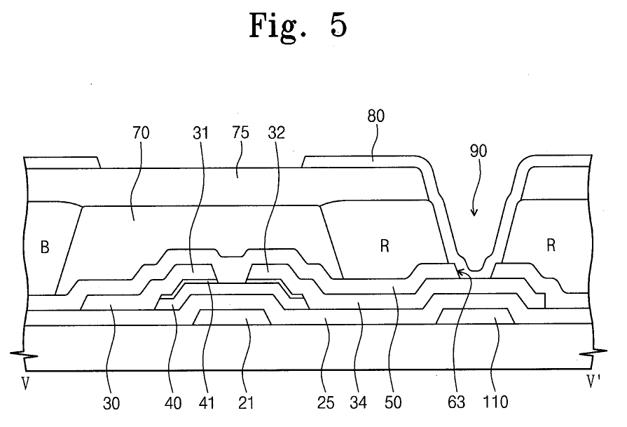

Hereinafter, a second exemplary embodiment of the display substrate according to the present invention will be described with reference to FIGS. 4 and 5. In the present embodiment, a description may be omitted or abbreviated for elements that are substantially the same as described in the first embodiment, and the description will focus on the differences between embodiments.

FIG. 4 is an enlarged view roughly showing a part of a pixel region of a display substrate according to a second exemplary embodiment of the present invention, and FIG. 5 is a cross sectional view taken along line V-V′ of FIG. 4.

Referring to FIGS. 4 and 5, a gate wiring including gate signal lines 20, gate electrodes 21 and gate pad electrodes 22, and storage wiring including storage lines 100 and storage electrodes 110 connected to the storage lines 100 and being made from the same material as the gate wiring 20, 21, 22 are disposed on the substrate 10.

A gate insulating layer 25 is disposed on the gate wiring 20, 21, 22 and the storage wiring 100,110, and semiconductor layers 40 and ohmic contact layers 41 are disposed on the gate insulating layer 25.

On the ohmic contact layer 41, data wiring including data signal lines 30, source electrodes 31, drain electrodes 32 and data pad electrodes 33 is disposed. In here, the drain electrode 34 and the storage electrode 110 form a storage capacitor by overlapping with each other, with the gate insulating layer 25 being therebetween.

A protective insulating layer 50 is disposed on the data wiring 30, 31, 33, 34. A contact hole 63 exposing the drain electrode 34 is formed in the protective insulating layer 50, and preferably in the region overlapping the storage electrode 110.

On the protective insulating layer, color filters R,G,B having an opening 91 exposing the contact hole 63 of the protective insulating layer 50, and black matrix 70 covering the gate signal line 20, data signal line 30 and the thin film transistor are disposed. Just as the first embodiment, the black matrix can have various shapes.

An organic layer 75 may be further disposed on the color filter R, G, B and the black matrix 70, and a pixel electrode 80 connected to the drain electrode 34 through the opening 91 and the contact hole 63 is disposed.

Hereinafter, a method of manufacturing the display substrate according to the exemplary embodiment of the present invention will be described. For the convenience of explanation, a method of manufacturing the display substrate of the first embodiment will be mainly described.

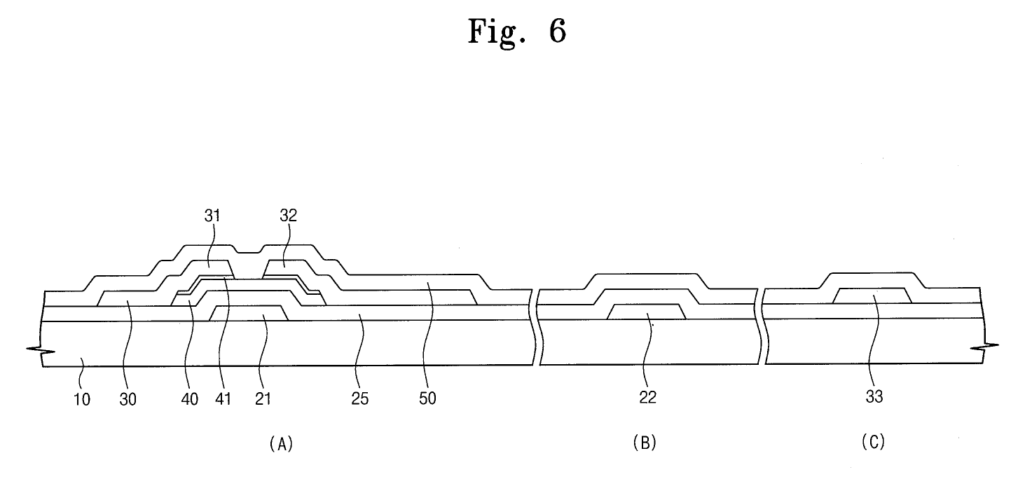

FIG. 6 to FIG. 14 are cross sectional views showing a method of manufacturing a display substrate shown in FIG. 1. In the present embodiment, FIG. 1 will be referred to as well as FIG. 6 to FIG. 14. A description may be omitted or abbreviated for structures that are already explained in FIG. 1 and process that are already known.

Referring to FIG. 6, gate wiring 20, 21, 22, a gate insulating layer 25, semiconductor layers 40, ohmic contact layers 41, data wiring 30, 31,32,33 and protective insulating layer 50 is formed on the insulating substrate 10. The semiconductor layer 40, the ohmic contact layer 41 and the data wiring 30,31,32,33 can be formed by using a single mask or separate masks. In FIG. 6 and thereafter, a part represented as A is a thin film transistor region, and parts represented as B, C are a gate pad region and a data pad region, respectively.

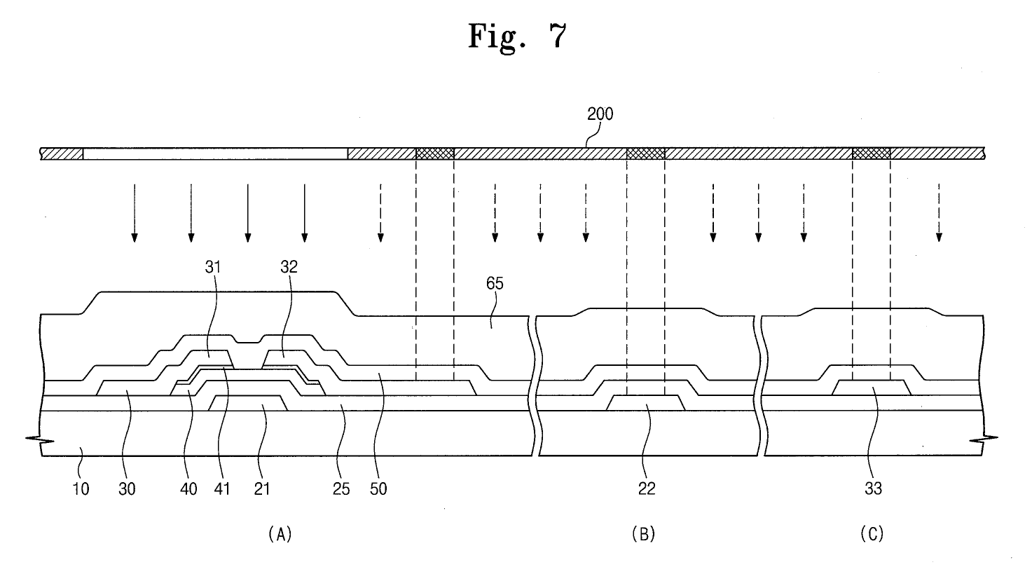

Referring to FIG. 7, an organic composition layer 65 containing photosensitive material is formed on the protective insulating layer 50, and then, exposed by using a first mask. A mask that has different light transmitting amount by the region thereof like a slit mask or a halftone mask, is used as the first mask. Namely, the first mask 200 has different light transmitting amount according to the brightness expressed in FIG. 6 such that the brightest region of the mask transmits the most amount of light and the darkest region of the mask does not transmit light. Therefore, the organic composition layer 65 disposed under the brightest region of the first mask 200 is exposed to the most light, and the organic composition layer 65 disposed under the darkest region of the first mask 200 is not exposed to the light, and the organic layer 65 disposed under the mid brightness region is exposed to the light amount in the middle of the other two cases.

In the present embodiment, a negative type of the organic composition layer is used, which means that a portion which is not exposed to the light is removed during a developing process.

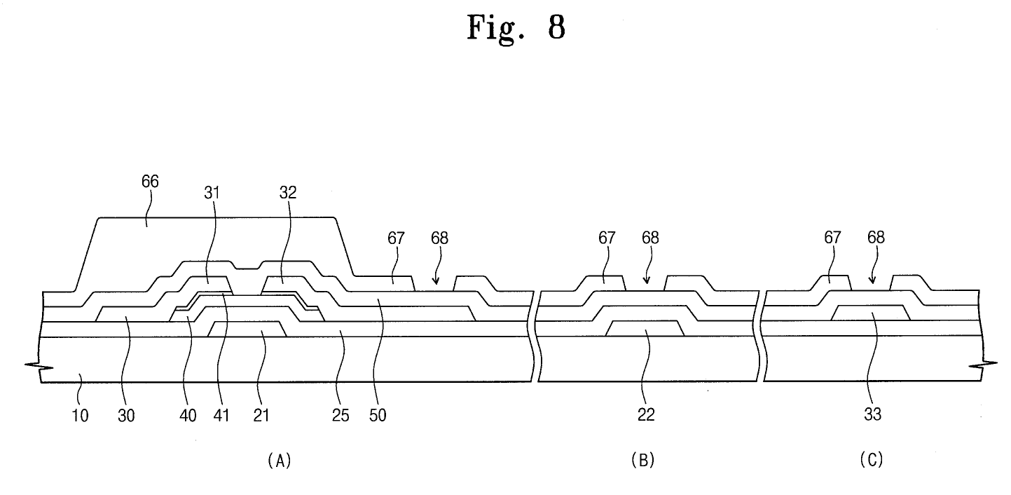

Referring to FIG. 8, a first black matrix pattern 66, 67, 68 is formed by developing the exposed organic composition layer 65. The first black matrix pattern includes a first portion 66 having a first thickness, a second portion 67 having a second thickness and a third portion exposing the protective insulating layer 50. The first portion 66 is a portion exposed to the most amount of light, and the third portion 68 is a portion that was not exposed to the light. Moreover, the first portion 66 is formed on the gate signal line 20, the data signal line 30 and the thin film transistor, and the third portion 68 is formed on the drain electrode 32, gate pad electrode 22 and the data pad electrode 33. The second portion 67 is formed on the region other than the region where the first and third portions 66, 68 are formed.

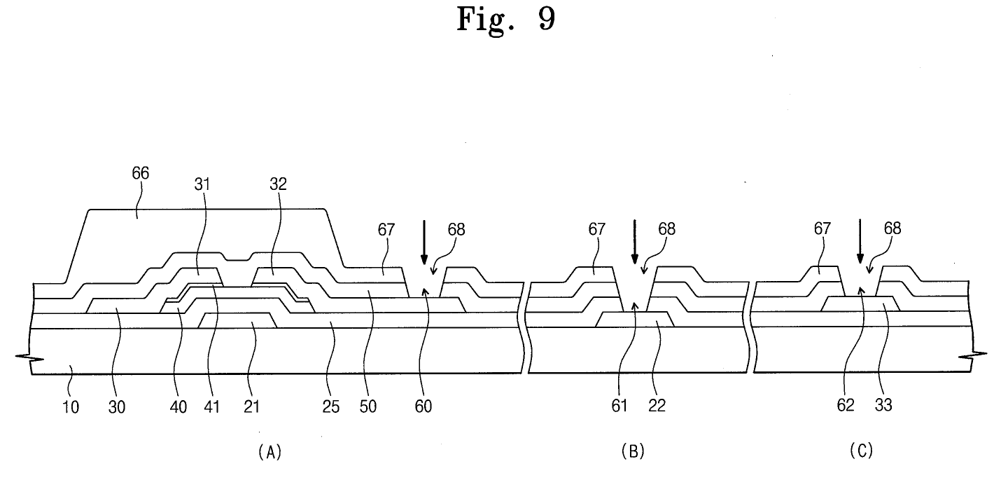

Referring to FIG. 9, first, second and third contact holes 60, 61, 62 are formed by dry etching the protective insulating layer. The first black matrix pattern is used as an etching mask, and a part of the first black matrix pattern is removed during the dry etching process.

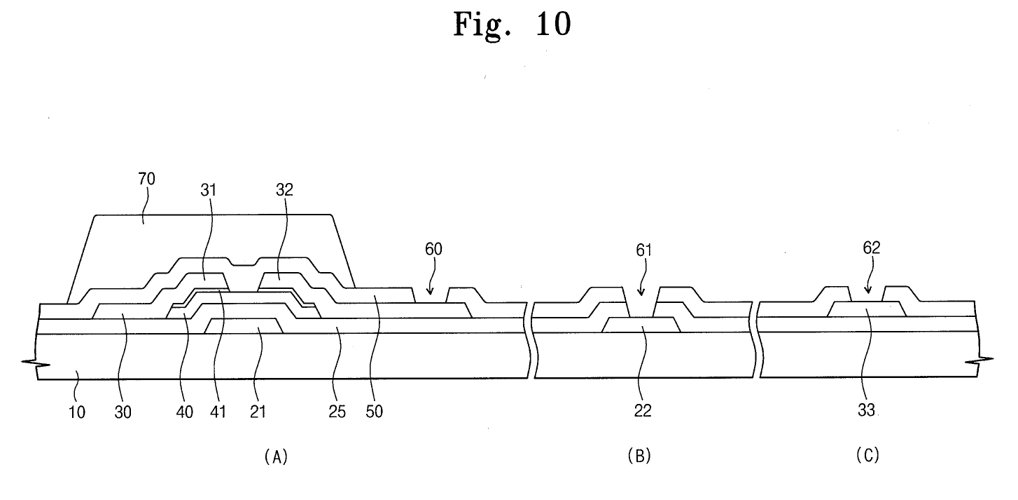

Referring to FIG. 10, a second black matrix pattern 70 is formed by removing the second portion 67 of the first black matrix pattern from the substrate 10. The thickness of the first portion 66 is also reduced during the process.

A black matrix of the display substrate according to the present invention is accomplished by the second black matrix pattern 70 and, referring to FIG. 1, the black matrix of the display substrate according to the present invention is formed only on the gate signal line 20, the data signal line 30 and the thin film transistor. Namely, black matrix materials on the rest of the pixel region except the edge region of the gate signal line 20, the data signal line 30 and the thin film transistor are removed during the process forming the second black matrix pattern.

Therefore, even if the first black matrix pattern is damaged during the etching process of the protective insulating layer 50, the black matrix materials on the pixel regions are substantially removed through the process forming the second black matrix pattern, which prevents the generation of stains caused by the damages of the layers on the pixel region, when driving the display.

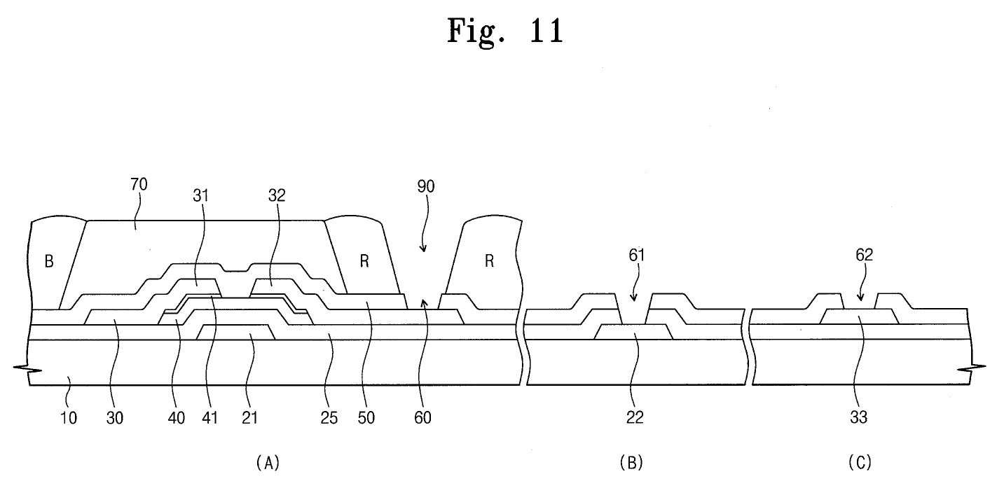

Referring to FIG. 11, red R, green G and blue B color filters are formed on each pixel region. The color filters can be formed, for example, by inkjet process, and have an opening 90 exposes the contact hole 60 therein.

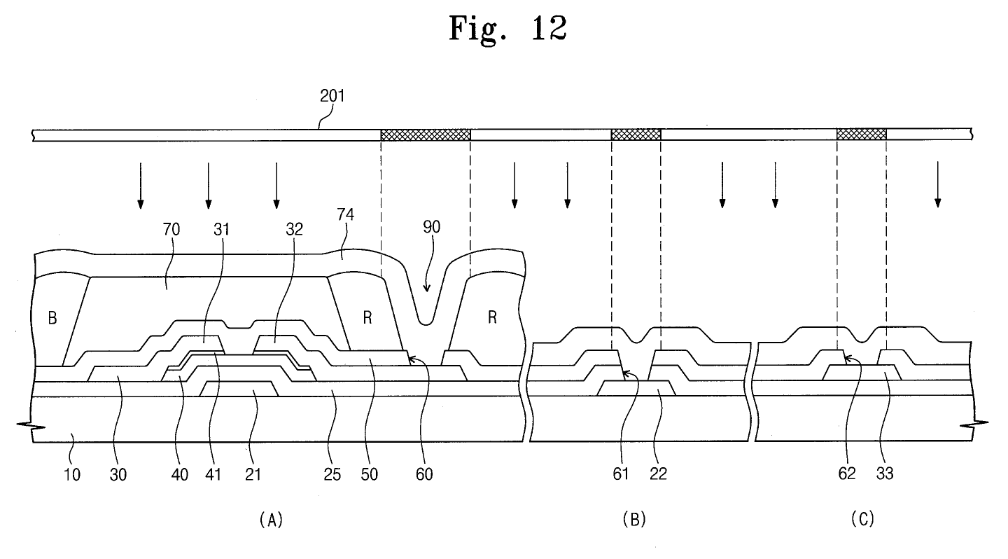

Referring to FIG. 12, a second organic composition layer 74 containing photosensitive material is formed on the substrate 10 and then, exposed by using a second mask 201. In the second mask 201 of FIG. 12, a bright portion transmits the light, and the dark portion does not transmit the light. Thus, the organic composition layer 74 disposed under the bright portion of the second mask 201 is exposed to the light and the organic composition layer 74 under the dark portion of the second mask 201 is not exposed to the light.

Meanwhile, as the exemplary case of the black matrix, a negative type of the organic composition layer 74 is also used in the present embodiment.

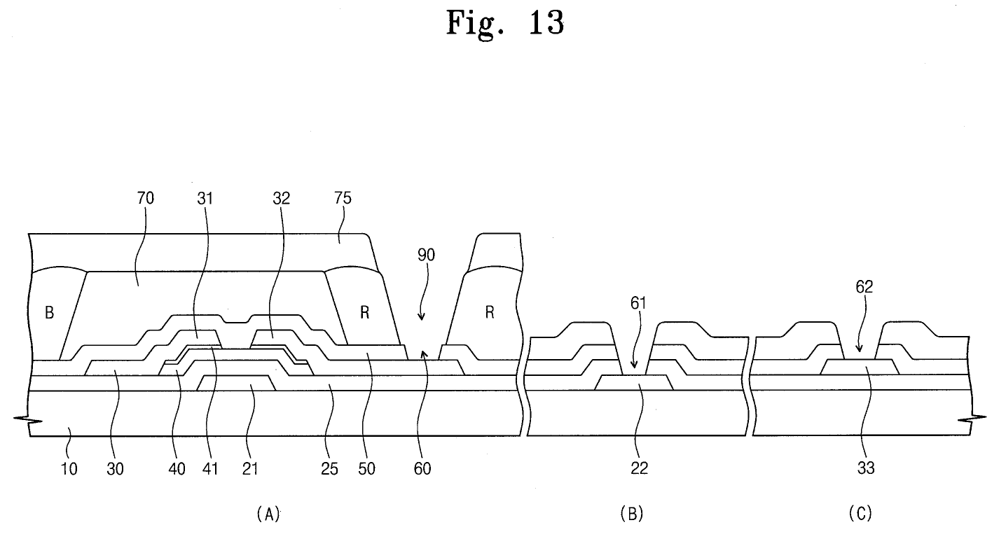

Referring to FIG. 13, an organic layer pattern 75 is formed by developing the exposed second organic composition layer 74. As described is FIG. 13, the organic layer pattern 75 is formed on the region other than the region where the first, second and third contact holes 60, 61, 62 are formed.

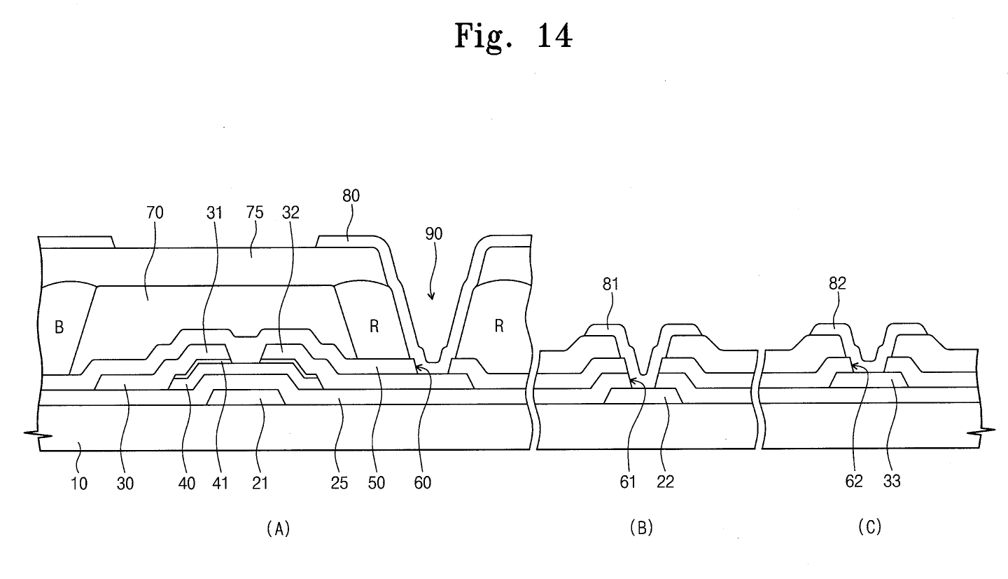

Referring to FIG. 14, a pixel electrode 80, a first auxiliary element 81 and a second auxiliary element 82 are formed on the organic layer pattern 75 by using a transparent conductive layer like ITO or IZO. The pixel electrode 80 is electrically connected to the drain electrode 32 through the opening 90 and the first contact hole 60. The first auxiliary element 81 is electrically connected to the gate pad electrode 22 through the second contact hole 61, and the second auxiliary element 82 is electrically connected to the data pad electrode 33 through the third contact hole 62.

As described above, the display substrates, the methods of manufacturing the display substrates according to the embodiments and the modifications of the present invention have advantages as follows.

Namely, the appearance of stains can be prevented when driving a display by preventing remnants generated in layers on a pixel region during a manufacturing processes from being left on the pixel region, which results in improvement of display quality.

Although exemplary embodiments of the present invention have been described, it is understood that the present invention should not be limited to these exemplary embodiments but various changes and modifications can be made by one of ordinary skilled in the art within the spirit and scope of the present invention.

What is claimed is:

1. A display substrate comprising:
a gate signal line formed on a substrate;
a data signal line being insulated from the gate signal line and crossing the gate signal line;
a thin film transistor connected to the gate signal line and the data signal line, respectively;
a black matrix formed on the thin film transistor and at least one of the gate signal line and data signal line, the black matrix comprising photosensitive material;
a protective insulating layer formed between the thin film transistor and the black matrix;
a pixel electrode electrically connected to the thin film transistor through a contact hole formed in the protective insulating layer;
a color filter formed between the protective insulating layer and the pixel electrode, and having an opening that exposes the contact hole.

2. The display substrate of claim 1, wherein the black matrix is formed by using a slit mask or a halftone mask.

3. The display substrate of claim 2, further comprising an organic layer formed between the pixel electrode and the black matrix, and between the pixel electrode and the color filter

4. The display substrate of claim 2, further comprising a storage line and a storage electrode, both of which being formed on a same layer as the gate signal line wherein, the pixel electrode is electrically connected to a drain electrode of the thin film transistor through the opening and the contact hole, and at least a part of the storage electrode overlaps the drain electrode.

5. A method of manufacturing a display substrate, the method comprising:
forming a gate wiring, a data wiring, a thin film transistor connected to the gate wiring and the data wiring respectively, and a protective insulating layer covering the gate wiring, the data wiring and the thin film transistor;
forming a first black matrix pattern on the protective insulating layer;
forming a protective insulating layer pattern by etching a part of the protective insulating layer by using the first black matrix pattern as an etching mask;
forming a second black matrix pattern exposing at least one pixel region by removing a part of the first black matrix pattern;
forming a color filter on the pixel region;
forming a pixel electrode electrically connected to the thin film transistor on at least a part of the color filter.

6. The method as recited in claim 5, wherein, forming the first black matrix pattern comprises:
Forming a first organic layer including photosensitive material on the protective insulating layer;
Exposing the first organic layer by using a slit mask or a halftone mask;
Forming a first portion having a first thickness, a second portion having a second thickness thinner than the first thickness, and a third portion exposing the protective insulating layer by developing the first organic layer

7. The method as recited in claim 6, wherein forming the protective
insulating layer pattern comprises
forming a contact hole exposing the drain electrode of the thin film transistor by dry etching the protective insulating layer exposed by the third portion

8. The method as recited in claim 7, wherein forming the second black matrix pattern comprises removing the second portion from the substrate.

9. The method as recited in claim 5, wherein the gate wiring comprises a gate signal line extended in a first direction, and a gate pad electrode connected to an end portion of the gate signal line,
and the data wiring comprises a data signal line extended in a second direction perpendicular to the first direction, and a data pad electrode connected to an end portion of the data signal line,
and the thin film transistor comprises a gate electrode connected to the gate signal line, a source electrode connected to the data signal line, and a drain electrode separated from the source electrode

10. The method as recited in claim 9, wherein forming the first black matrix pattern comprises,
Forming a first organic layer including photosensitive material on the protective insulating layer;
Exposing the first organic layer by using a slit mask or a halftone mask;
Forming a first portion having first thickness, a second portion having second thickness thinner than the first thickness, and a third portion exposing the protective insulating layer,
wherein, the first portion is formed on at least a portion of the thin film transistor, and at least one of the gate signal line and the data signal line,
and the third portion is formed on the drain electrode, the gate pad electrode and the data pad electrode

11. The method as recited in claim 10, wherein forming the protective insulating layer comprises
forming a first contact hole exposing the drain electrode, a second contact hole exposing the gate pad electrode and a third contact hole exposing the data pad electrode, respectively, by dry etching the protective insulating layer exposed by the third portion.

12. The method as recited in claim 11, wherein forming the second black matrix pattern comprises removing the second portion from the substrate.

13. The method as recited in claim 5, further comprising
Forming an organic layer pattern on the second black matrix pattern and the color filter before forming the pixel electrode

14. The method as recited in claim 13, wherein forming the organic layer pattern comprises:
Forming a second organic layer including photosensitive material on the second black matrix pattern and the color filter;
Exposing the second organic layer by using a mask; and,
Developing the second organic layer

15. A display substrate comprising:
a black matrix formed on a thin film transistor and at least one of the gate signal line and data signal line, the black matrix comprising photosensitive material;
a protective insulating layer formed between the thin film transistor and the black matrix;
a pixel electrode electrically connected to the thin film transistor through a contact hole formed in the protective insulating layer, the contact hole formed by using the black matrix as a mask.
